(19) United States
(12) Patent Application Publication
(10) Pub. No.: US 2017/0117813 A1
(43) Pub. Date: Apr. 27, 2017

(54) METHOD AND SYSTEM FOR TESTING A POWER SUPPLY UNIT

(71) Applicant: Quanta Computer Inc., Taoyuan City (TW)

(72) Inventor: Wen-Kai LEE, Taoyuan City (TW)

(21) Appl. No.: 14/919,064

(22) Filed: Oct. 21, 2015

(51) Int. Cl. H02M 3/335; G01R 31/40; H02M 1/08

(52) U.S. Cl. CPC H02M 3/33523; H02M 1/08; G01R 31/40; H02M 2001/0009

(57) ABSTRACT

Various embodiments of the present technology provide methods for testing one or more components of a power supply unit (PSU) of a server system to identify potential issues before the PSU actually fails. Some embodiments provide systems and methods for determining a value of a performance characteristic (e.g., a current, voltage or impedance) of one or more components of a PSU of a server system. Thereafter, in response to the value of the performance characteristic being inconsistent with a predetermined criterion, the systems and methods involve generating a corresponding alarm signal.

### TECHNICAL FIELD

The present technology relates generally to server systems in a telecommunications network.

### BACKGROUND

Modern server farms or datacenters typically employ a large number of servers to handle processing needs for a variety of application services. Each server handles various operations and requires a certain level of power consumption to maintain these operations. Some of these operations are “mission critical” operations, interruptions to which may lead to significant security breach or revenue losses for users associated with these operations.

Some typical types of interruptions include failures or faults at power supply units (PSUs) of a server system. A failure or a fault in one or more PSUs can force a sudden shutdown of a server system, possibly resulting in data loss or even damage to the server system. Therefore, there is a need to test and monitor the operation of a PSU for potential issues before the PSU actually fails.

### SUMMARY

Systems and methods in accordance with various embodiments of the present technology provide a solution to the above-mentioned problems by testing one or more components of a power supply unit (PSU) of a server system to identify potential issues before the PSU actually fails. More specifically, various embodiments of the present technology provide systems and methods for determining a value of a performance characteristic (e.g., a current, voltage, or impedance) of one or more components of a PSU of a server system. Thereafter, in response to the value of the performance characteristic being inconsistent with a predetermined criterion, the systems and methods involve generating a corresponding alarm signal.

In some embodiments, a predetermined criterion for testing a component of the PSU may include, but is not limited to, an acceptable range of values for a performance characteristic (e.g., a current, voltage or impedance) of the corresponding component. The performance characteristic of the component of the PSU can be compared with the predetermined criterion using a comparator. The comparator may be integrated into the PSU or discretely connected to the corresponding component of the PSU. Components of a PSU may include, but are not limited to, a filter, input rectifier, power factor correction circuit, phase shift converter, transformer, output rectifier, output field-effect transistor (FET), or one or more multipoint control units (MCUs).

Some embodiments can collect historical data of performance characteristics of components of PSUs, which may include historical data associated with PSU failures. The collected historical data can be analyzed according to one or more machine learning algorithms and used to define a criterion for testing a corresponding component of a PSU. In some embodiments, collected historical data may also include service times of the PSUs and loading information of corresponding PSUs during a respective service period. A criterion for testing a component of a PSU may be dynamically determined using the one or more machine learning algorithms.

In some implementations, collected historical data of performance characteristics of components of PSUs can serve as an input feature set for the one or more machine learning algorithms to determine a test criterion for a corresponding component of a PSU. The one or more machine learning algorithms may include, but are not limited to, at least one of linear regression model, neural network model, support vector machine based model, Bayesian statistics, case-based reasoning, decision trees, inductive logic programming, Gaussian process regression, group method of data handling, learning automata, random forests, ensembles of classifiers, ordinal classification, or conditional random fields.

### BRIEF DESCRIPTION OF THE DRAWINGS

In order to describe the manner in which the above-recited and other advantages and features of the disclosure can be obtained, a more particular description of the principles briefly described above will be rendered by reference to specific examples thereof which are illustrated in the appended drawings. Understanding that these drawings depict only example aspects of the disclosure and are not therefore to be considered to be limiting of its scope, the principles herein are described and explained with additional specificity and detail through the use of the accompanying drawings in which:

FIG. 1A illustrates a schematic block diagram of an exemplary power supply unit (PSU) in accordance with an implementation of the present technology;

FIG. 1B illustrates a schematic block diagram of an exemplary server system in accordance with an implementation of the present technology;

FIG. 2 illustrates an exemplary method of testing a PSU of a server system in accordance with an implementation of the present technology;

FIG. 3 illustrates an exemplary computing device in accordance with various implementations of the technology;

FIGS. 4A and 4B illustrate exemplary systems in accordance with various embodiments of the present technology;

FIGS. 5A-5C illustrate exemplary correlations between drain-to-source on resistance, a junction temperature and drain-to-source voltage of a switching MOSFET in accordance with various embodiments of the present technology; and

FIG. 6 illustrates an exemplary criterion to determine whether a component of a PSU operates normal in accordance with various embodiments of the present technology.

### DETAILED DESCRIPTION

More specifically, various embodiments of the present technology provide systems and methods for determining a performance characteristic (e.g., a current, voltage or impedance) of one or more components of a PSU of a server system by comparing a value of the performance characteristic with a predetermined criterion and, in response to the value of the performance characteristic being inconsistent with the predetermined criterion, generating a corresponding alarm signal. The PSU of the server system may include a filter, input rectifier, power factor correction circuit, phase shift converter, transformer, output rectifier, output field-effect transistor (FET), or one or more multipoint control units (MCUs).

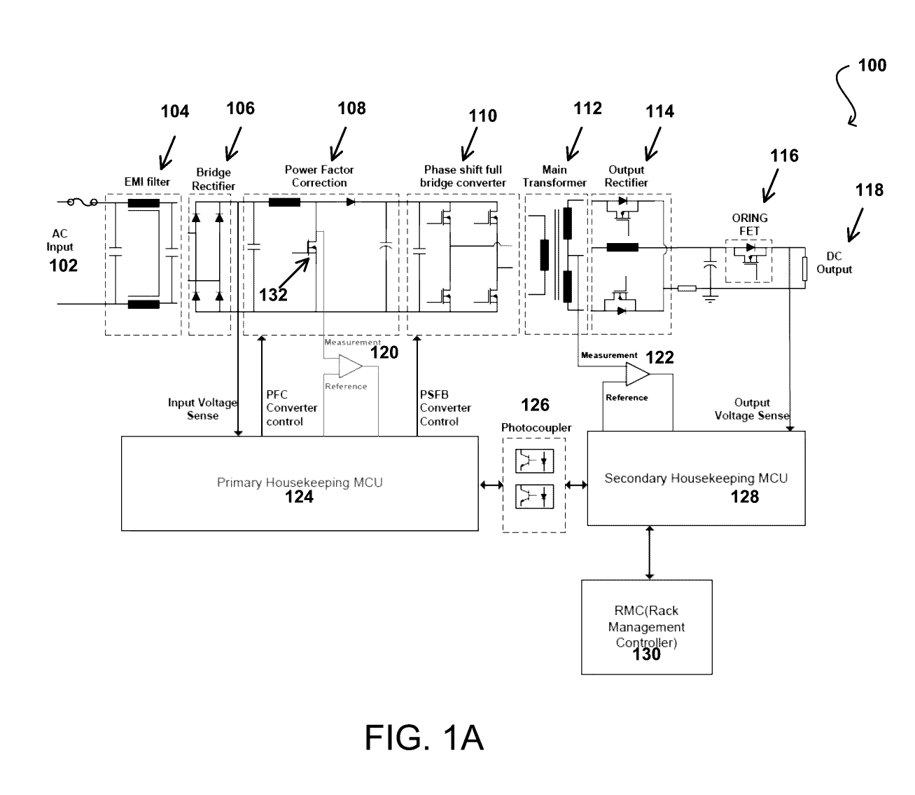

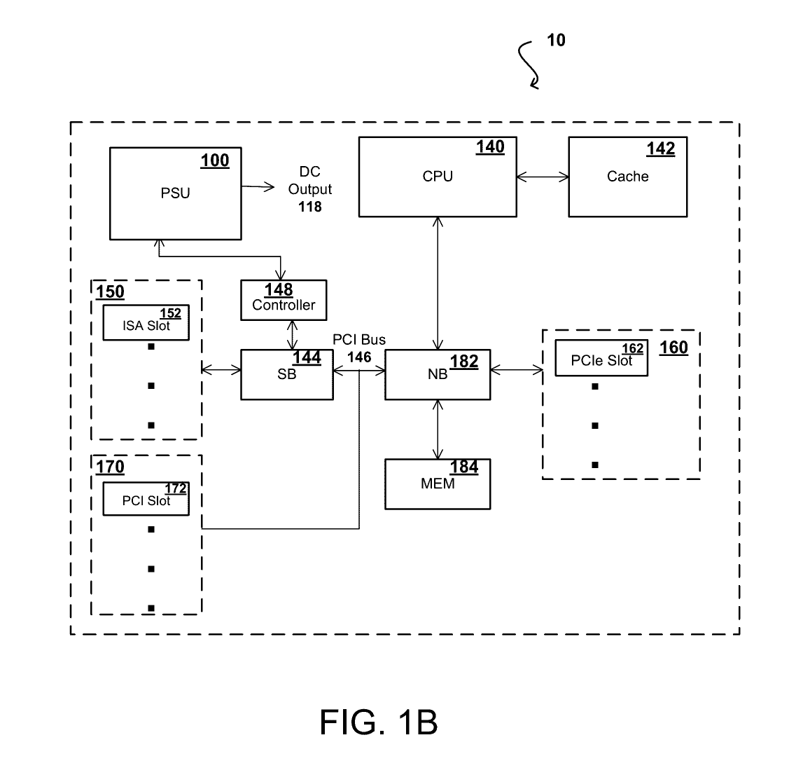

FIG. 1A illustrates a schematic block diagram of an exemplary power supply unit (PSU) 100 of a server system in accordance with an implementation of the present technology. In this example, the PSU 100 includes an AC input 102, an EMI filter 104 that is coupled to the AC input 102, a bridge rectifier 106 coupled to the EMI filter 104, a power factor correction (PFC) 108 coupled to the bridge rectifier 106, a phase shift full bridge converter 110 coupled to the PFC 108, a main transformer 112 coupled to the phase shift full bridge converter 110, an output rectifier 114 coupled to the main transformer 112, and an ORING FET 116 coupled to the output rectifier 114 and an DC output 118.

The EMI filter 104 is configured to extract and remove electromagnetic noises from the AC input voltage 102. The bridge rectifier 106 is configured to convert an AC input voltage from the EMI filter 104 to a high DC voltage while the output rectifier 114 is configured to convert an DC voltage level from the main transformer 112 into a DC voltage to the ORING FET 116. The rectifiers 106 and 114 may include, but are not limited to, a semiconductor diode, silicon controlled rectifier, other silicon-based semiconductor switches, copper and selenium oxide rectifiers, mercury-arc valves, and vacuum tube diodes.

The ORING FET 116 is configured to allow a current of the DC output 118 to only flow in one direction and thus can isolate a fault of the PSU 100 from other power sources (e.g., other PSUs) of the server system 10. In the event of the PSU 100 fails, the ORING FET 116 can protect a redundant bus (not shown) and the server system 10 from a failure of the PSU 100 and allows the server system 10 to run off the other power sources.

The PFC 108 is configured to bring a power factor of the PSU close to 1 by adding a capacitor or inductor that acts to cancel the inductive or capacitive effects of a load of the PSU. The power factor is a ratio of the real power flowing to a load of the PSU 100 to an apparent power in the PSU.

In this example, the PSU 100 further includes a primary housekeeping multipoint control (MCU) 124, and a secondary MCU 128. The primary housekeeping MCU 124 is coupled to the bridge rectifier 106, the PFC 108 and the phase shift full bridge converter 110. The secondary MCU 128 is coupled to the primary housekeeping MCU 124 via a photocoupler 126, the ORING FET 116, and the DC output 118

The primary housekeeping multipoint control (MCU) 124 is configured to collect or sense performance data (e.g., an output voltage from the bridge rectifier 106) of components on the primary side of the main transformer 112 and further control operations of primary side components (e.g., the PFC 108 and PSFB converter 110) of the PSU 100.

The primary housekeeping MCU 124 is further coupled to a drain of a transistor 132 through a comparator 120. The comparator 120 can compare a drain voltage of the transistor 132 with a reference voltage. The reference voltage can be predetermined or dynamically provided by the primary housekeeping MCU 124.

In some embodiments, a comparator can be used to connect the primary housekeeping MCU 124 with any component on the primary side of the main transformer 112 and used to test whether a voltage value at the test point is consistent with a predetermined voltage.

In some embodiments, the primary housekeeping MCU 124 can be coupled a component of the PSU 100 through a current sensing sub-circuit. A sensed current of the component of the PSU 100 can be compared with a predetermined current range and used to determine a health status of the component. For example, the component is determined to be healthy, if the sensed current is consistent with the predetermined current range.

In some embodiments, an internal impedance of a component of the PSU 100 can be sensed by the primary housekeeping MCU 124 through an impedance sensing sub-circuit (e.g., by measuring small AC or DC currents and voltages). A sensed internal impedance of the component of the PSU 100 can be compared with a predetermined impedance range and used to determine a health status of the component.

In some embodiments, in response to a value of a particular performance characteristic of a component of the PSU 100 being inconsistent with a predetermine criterion, the primary MCU 124 can send out a corresponding alarm signal to a controller of the server system 10. In some implementations, the primary MCU 124 may shut down and restart the PSU 100 when a particular performance data fails.

The secondary MCU 128 is configured to sense performance data (e.g., an output current or voltage from the output rectifier 114 or the ORING FET 116) of components on the secondary side of the main transformer 112. The secondary MCU 128 is further configured to send out sensed performance data to the primary MCU 124 via the photocoupler 126 or a rack management controller (RMC) 130 via a serial peripheral interface (SPI) bus, an inter-integrated circuit (I2C) bus, a power management bus (PMBus), a controller area network (CAN) bus, or a bus that supports an electronic industries alliance (EIA), RS-232, RS-422, or RS-485 standard. In some embodiments, the secondary MCU 128 may directly send out an alarm signal in response to a particular performance data being inconsistent with a corresponding criterion.

FIG. 1B illustrates a schematic block diagram of an exemplary server system 10 in accordance with an implementation of the present technology. In this example, the server system 10 comprises at least one microprocessor or CPU 140 connected to a Cache 142, a main Memory 184, and one or more PSUs 100 that provides power to the server system 100. The main Memory 184 can be coupled to the CPU 140 via a north bridge (NB) logic 182. A memory control module (not shown) can be used to control operations of the Memory 184 by asserting necessary control signals during memory operations. The main Memory 184 may include, but is not limited to, dynamic random access memory (DRAM), double data rate DRAM (DDR DRAM), static RAM (SRAM), or other types of suitable memory.

In some implementations, the CPU 140 can be multi-core processors, each of which is coupled together through a CPU bus connected to the NB logic 182. In some implementations, the NB logic 182 can be integrated into the CPU 140. The NB logic 182 can also be connected to a plurality of peripheral component interconnect express (PCIe) ports 160 and a south bridge (SB) logic 144 (optional). The plurality of PCIe ports 160 can be used for connections and buses such as PCI Express ×1, USB 2.0, SMBus, SIM card, future extension for another PCIe lane, 1.5 V and 3.3 V power, and wires to diagnostics LEDs on the server's chassis.

In this example, the NB logic 182 and the SB logic 144 (optional) are connected by a peripheral component interconnect (PCI) Bus 146. The PCI Bus 146 can support function on the CPU 140 but in a standardized format that is independent of any of CPU's native buses. The PCI Bus 146 can be further connected to a plurality of PCI slots 170 (e.g., a PCI Slot 172). Devices connect to the PCI Bus 146 may appear to a bus controller (not shown) to be connected directly to a CPU bus, assigned addresses in the CPU 140's address space, and synchronized to a single bus clock. PCI cards can be used in the plurality of PCI slots 170 include, but are not limited to, network interface cards (NICs), sound cards, modems, TV tuner cards, disk controllers, video cards, small computer system interface (SCSI) adapters, and personal computer memory card international association (PCMCIA) cards.

The SB logic 144 (optional) can couple the PCI Bus 146 to a plurality of expansion cards or slots 150 (e.g., an ISA slot 152) via an expansion bus. The expansion bus can be a bus used for communications between the SB logic 144 (optional) and peripheral devices, and may include, but is not limited to, an industry standard architecture (ISA) bus, PC/104 bus, low pin count bus, extended ISA (EISA) bus, universal serial bus (USB), integrated drive electronics (IDE) bus, or any other suitable bus that can be used for data communications for peripheral devices.

In the example, the SB logic 144 (optional) is further coupled to a Controller 148 that is connected to the one or more PSUs 100. The one or more PSUs 100 are configured to supply powers to various component of the server system 100, such as the CPU 140, Cache 142, NB logic 182, PCIe slots 160, Memory 184, SB logic 144 (optional), ISA slots 150, PCI slots 170, and Controller 148. After being powered on, the server system 10 is configured to load software application from memory, computer storage device, or an external storage device to perform various operations.

In some implementations, the Controller 148 can be a baseboard management controller (BMC), rack management controller (RMC), a keyboard controller, or any other suitable type of system controller. In some embodiments, the Controller 148 can be configured to control operations of the one or more PSUs 100 in the server system and/or other applicable operations.

Some implementations enable the Controller 148 to collect historical data of the server system 10 and the one or more PSUs 100. In some implementations, service times of the one or more PSUs 100 and loading information of the PSU 100 during a corresponding service period are also collected. As used herein with respect to a server system or portions thereof, the term “load” or “loading” refers to the amount of computational work that the server system 10 (or portions thereof) has performed or the amount of power that the one or more PSUs 100 have supplied at a time of interest.

Collected present and/or historical loading information can be analyzed and used to determine a criterion for testing a component of the one or more PSUs 100 according to one or more machine-learning algorithms. In some embodiments, the one or more machine-learning algorithms can further include at least one of a linear regression model, neural network model, support vector machine based model, Bayesian statistics, case-based reasoning, decision trees, inductive logic programming, Gaussian process regression, group method of data handling, learning automata, random forests, ensembles of classifiers, ordinal classification, or conditional random field. For example, a neural network model can be used to analyze historical loading information and to capture complex correlation between a criterion for testing a component of the one or more PSUs 100 and service times and loading history of the one or more PSUs 100.

In some implementations, the Controller 148 can collect parameters (e.g., temperature, cooling fan speeds, power status, memory and/or operating system (OS) status) from different types of sensors that are built into the server system 100. In some implementations, the Controller 148 can also be configured to take appropriate action when necessary. For example, in response to any parameter on the different types of sensors that are built into the server system 10 going beyond preset limits, which can indicate a potential failure of the server system 100, the Controller 148 can be configured to perform a suitable operation in response to the potential failure. The suitable operation can include, but is not limited to, sending an alert to the CPU 140 or a system administrator over a network, or taking some corrective action such as resetting or power cycling the node to get a hung OS running again).

Although only certain components are shown within the server system 10 in FIG. 1B and the one or more PSUs 100 in FIG. 1A, various types of electronic or computing components that are capable of processing or storing data, or receiving or transmitting signals can also be included in server system 10 and the one or more PSUs 100. Further, the electronic or computing components in the server system 10 and the one or more PSUs 100 can be configured to execute various types of application and/or can use various types of operating systems. These operating systems can include, but are not limited to, Android, Berkeley Software Distribution (BSD), iPhone OS (iOS), Linux, OS X, Unix-like Real-time Operating System (e.g., QNX), Microsoft Windows, Window Phone, and IBM z/OS.

Depending on the desired implementation for the server system 10 and the one or more PSUs 100, a variety of networking and messaging protocols can be used, including but not limited to TCP/IP, open systems interconnection (OSI), file transfer protocol (FTP), universal plug and play (UPnP), network file system (NFS), common internet file system (CIFS), AppleTalk etc. As would be appreciated by those skilled in the art, the server system 10 illustrated in FIG. 1 is used for purposes of explanation. Therefore, a network system can be implemented with many variations, as appropriate, yet still provide a configuration of network platform in accordance with various embodiments of the present technology.

In exemplary configuration of FIG. 1B and FIG. 1A, the server system 10 and the one or more PSUs 100 can also include one or more wireless components operable to communicate with one or more electronic devices within a computing range of the particular wireless channel. The wireless channel can be any appropriate channel used to enable devices to communicate wirelessly, such as Bluetooth, cellular, NFC, or Wi-Fi channels. It should be understood that the device can have one or more conventional wired communications connections, as known in the art. Various other elements and/or combinations are possible as well within the scope of various embodiments.

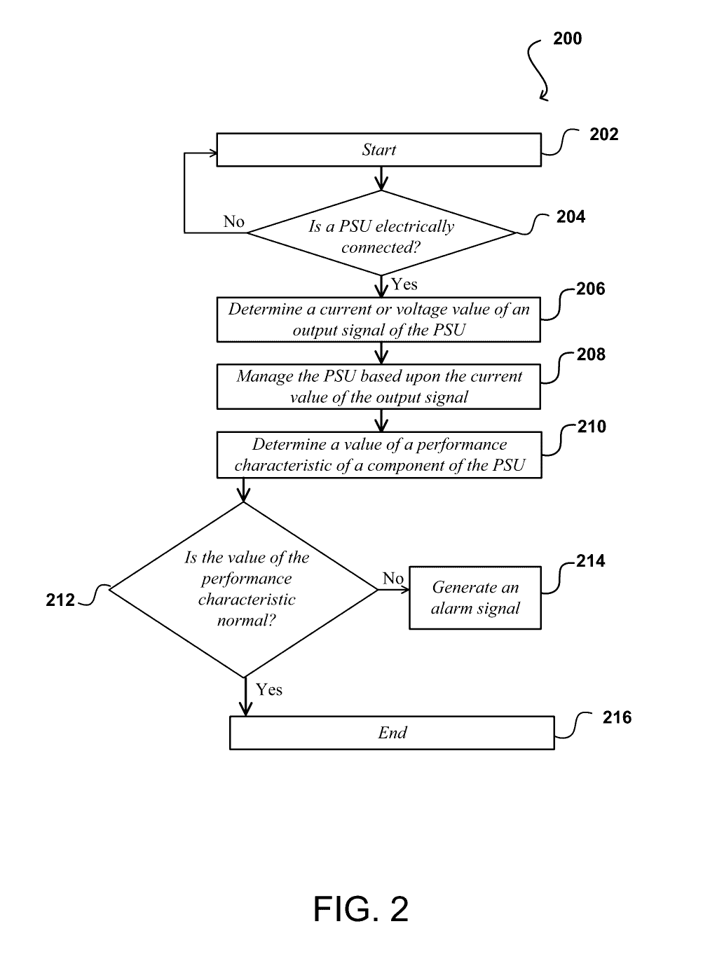

FIG. 2 illustrates an exemplary method 200 of testing a power supply unit (PSU) of a server system in accordance with an implementation of the present technology. It should be understood that the exemplary method 200 is presented solely for illustrative purposes and that in other methods in accordance with the present technology can include additional, fewer, or alternative steps performed in similar or alternative orders, or in parallel. The exemplary method 200 starts at step 202.

At step 204, the PSU is tested to determine whether the PSU is electronically connected with a server system (e.g., as illustrated in FIG. 1B). For example, a current or voltage output signal from the PSU can be tested to determine whether the PSU is connected to the server system. In some implementations, one or more position sensors can be used to determine whether the PSU is inserted into a corresponding PSU slot of the server system.

At step 206, a current or voltage value of an output signal of the PSU can be determined. Based upon the current value, the PSU can be managed at step 208. For example, as illustrated in FIG. 1A, an output current or voltage of the PSU 100 can be sensed by the secondary housekeeping MCU 128 and sent to the primary housing MCU 124. Based upon the output current or voltage of the PSU 100, the primary housekeeping MCU 124 can send a PFC converter control signal to the PFC 108 or a PSFB converter control signal to the PSFB converter 110 to manage operations of the PSU 100.

At step 210, a value of a performance characteristic of a component of the PSU can be determined. In some implementations, a sensing circuit (e.g., a current sensing circuit, a comparator or an impedance sending circuit) can be used to connect to the component of the PSU and test the performance characteristic of the component.

A value of the performance characteristic of the component can be compared with a criterion of the corresponding component to determine whether or not the component is normal, at step 212. In response to determining that the value of the performance characteristic of the component being abnormal, an alarm signal can be generated at step 214.

For example, as illustrated in FIG. 1A, the comparator 120 connected to a drain of the switching MOSFET 132 can be used to compare a drain-to-source voltage of the switching MOSFET 132 to a reference voltage. In response to determining that the drain-to-source voltage is abnormal, the primary housekeeping MCU 124, as illustrated in FIG. 1A, can generate and send out a high-stress voltage alarm signal.

For another example, the primary housekeeping MCU 124, as illustrated in FIG. 1A, can test an internal impedance of a switching MOSFET 132 at the primary side. In response to determining that the internal impedance of the MOSFET 132 is abnormal, the primary housekeeping MCU 124 can generate and send out an impedance aging alarm signal.

In some implementations, historical data of performance characteristics of components of PSUs can be collected and analyzed. The collected historical data can be analyzed according to one or more machine learning algorithms and used to define a criterion (e.g., an internal impedance range or drain-to-source voltage range for a switching MOSFET) for testing a component of a PSU. In some embodiments, based upon a service time of a PSU and loading conditions of the PSU during a respective service period, a criterion for testing a component of a PSU may be dynamically determined using the one or more machine learning algorithms.

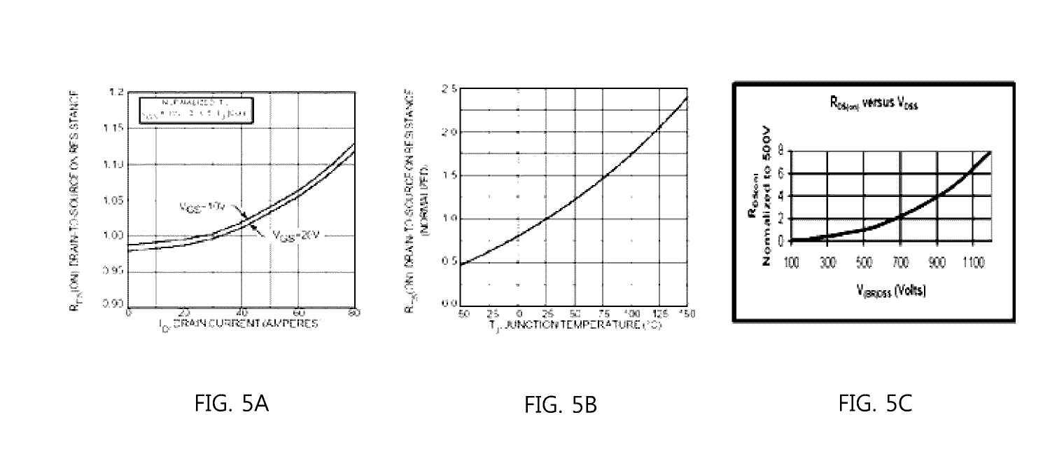

For example, a drain-to-source on resistance (R_{DS}(on)) of a switching MOSFET may increase when a drain current (I_{D}), a junction temperature (T_{J}) or a drain-to-source voltage (V_{DSS}) of the switching MOSFET increases, as illustrated in FIG. 5A, FIG. 5B and FIG. 5C, respectively. Variations of a drain current and junction temperature may have different impacts on R_{DS}(on) of the switching MOSFET. For instances, when the junction temperature of the switching MOSFET increases from 25° C. to 125° C., R_{DS}(on) of the switching MOSFET may increase more than two times. On the other hand, when the drain current of the switching MOSFET increases two times from 20 Amperes to 40 Amperes, R_{DS}(on) of the switching MOSFET may only increase 6 percent.

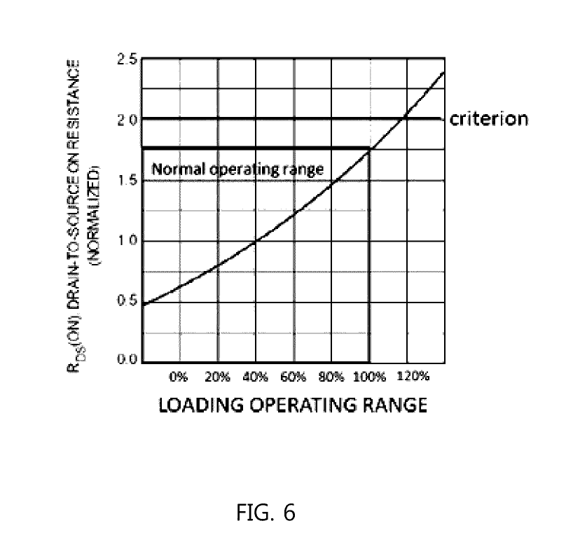

In some embodiments, one or more machine learning algorithms can measure a drain current of the switching MOSFET using a current sensor, a drain-to-source voltage of the switching MOSFET using a voltage divider circuit, and a junction temperature of the switching MOSFET using a thermistor. The one or more machine learning algorithms may also collect a date code of a corresponding PSU. A criterion for testing a component may be determined based at least upon a service time of the PSU, or a current, voltage or temperature of the component. For example, a R_{DS}(on) of a switching MOSFET may be in a range of 0.5 ohm to 1.75 ohm, as illustrated in FIG. 6. A criterion for testing the switching may be set as a threshold R_{DS}(on) value of 2.0 ohm. When the R_{DS}(on) of the switching MOSFET goes above the threshold R_{DS}(on) value, an alarm signal can be generated.

### TERMINOLOGIES

A computer network is a geographically distributed collection of nodes interconnected by communication links and segments for transporting data between endpoints, such as personal computers and workstations. Many types of networks are available, with the types ranging from local area networks (LANs) and wide area networks (WANs) to overlay and software-defined networks, such as virtual extensible local area networks (VXLANs).

LANs typically connect nodes over dedicated private communications links located in the same general physical location, such as a building or campus. WANs, on the other hand, typically connect geographically dispersed nodes over long-distance communications links, such as common carrier telephone lines, optical lightpaths, synchronous optical networks (SONET), or synchronous digital hierarchy (SDH) links. LANs and WANs can include layer 2 (L2) and/or layer 3 (L3) networks and devices.

The Internet is an example of a WAN that connects disparate networks throughout the world, providing global communication between nodes on various networks. The nodes typically communicate over the network by exchanging discrete frames or packets of data according to predefined protocols, such as the Transmission Control Protocol/Internet Protocol (TCP/IP). In this context, a protocol can refer to a set of rules defining how the nodes interact with each other. Computer networks can be further interconnected by an intermediate network node, such as a router, to extend the effective “size” of each network.

Overlay networks generally allow virtual networks to be created and layered over a physical network infrastructure. Overlay network protocols, such as Virtual Extensible LAN (VXLAN), Network Virtualization using Generic Routing Encapsulation (NVGRE), Network Virtualization Overlays (NVO3), and Stateless Transport Tunneling (STT), provide a traffic encapsulation scheme which allows network traffic to be carried across L2 and L3 networks over a logical tunnel. Such logical tunnels can be originated and terminated through virtual tunnel end points (VTEPs).

Moreover, overlay networks can include virtual segments, such as VXLAN segments in a VXLAN overlay network, which can include virtual L2 and/or L3 overlay networks over which VMs communicate. The virtual segments can be identified through a virtual network identifier (VNI), such as a VXLAN network identifier, which can specifically identify an associated virtual segment or domain.

Network virtualization allows hardware and software resources to be combined in a virtual network. For example, network virtualization can allow multiple numbers of VMs to be attached to the physical network via respective virtual LANs (VLANs). The VMs can be grouped according to their respective VLAN, and can communicate with other VMs as well as other devices on the internal or external network.

Network segments, such as physical or virtual segments, networks, devices, ports, physical or logical links, and/or traffic in general can be grouped into a bridge or flood domain. A bridge domain or flood domain can represent a broadcast domain, such as an L2 broadcast domain. A bridge domain or flood domain can include a single subnet, but can also include multiple subnets. Moreover, a bridge domain can be associated with a bridge domain interface on a network device, such as a switch. A bridge domain interface can be a logical interface which supports traffic between an L2 bridged network and an L3 routed network. In addition, a bridge domain interface can support internet protocol (IP) termination, VPN termination, address resolution handling, MAC addressing, etc. Both bridge domains and bridge domain interfaces can be identified by a same index or identifier.

Furthermore, endpoint groups (EPGs) can be used in a network for mapping applications to the network. In particular, EPGs can use a grouping of application endpoints in a network to apply connectivity and policy to the group of applications. EPGs can act as a container for buckets or collections of applications, or application components, and tiers for implementing forwarding and policy logic. EPGs also allow separation of network policy, security, and forwarding from addressing by instead using logical application boundaries.

Cloud computing can also be provided in one or more networks to provide computing services using shared resources. Cloud computing can generally include Internet-based computing in which computing resources are dynamically provisioned and allocated to client or user computers or other devices on-demand, from a collection of resources available via the network (e.g., “the cloud”). Cloud computing resources, for example, can include any type of resource, such as computing, storage, and network devices, virtual machines (VMs), etc. For instance, resources can include service devices (firewalls, deep packet inspectors, traffic monitors, load balancers, etc.), compute/processing devices (servers, CPU's, memory, brute force processing capability), storage devices (e.g., network attached storages, storage area network devices), etc. In addition, such resources can be used to support virtual networks, virtual machines (VM), databases, applications (Apps), etc.

Cloud computing resources can include a “private cloud,” a “public cloud,” and/or a “hybrid cloud.” A “hybrid cloud” can be a cloud infrastructure composed of two or more clouds that inter-operate or federate through technology. In essence, a hybrid cloud is an interaction between private and public clouds where a private cloud joins a public cloud and utilizes public cloud resources in a secure and scalable manner. Cloud computing resources can also be provisioned via virtual networks in an overlay network, such as a VXLAN.

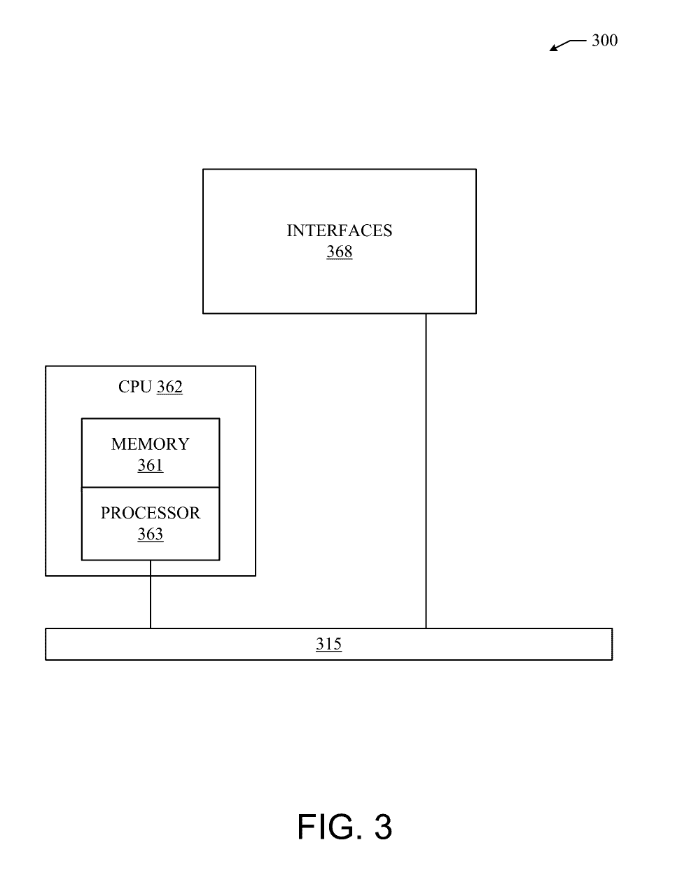

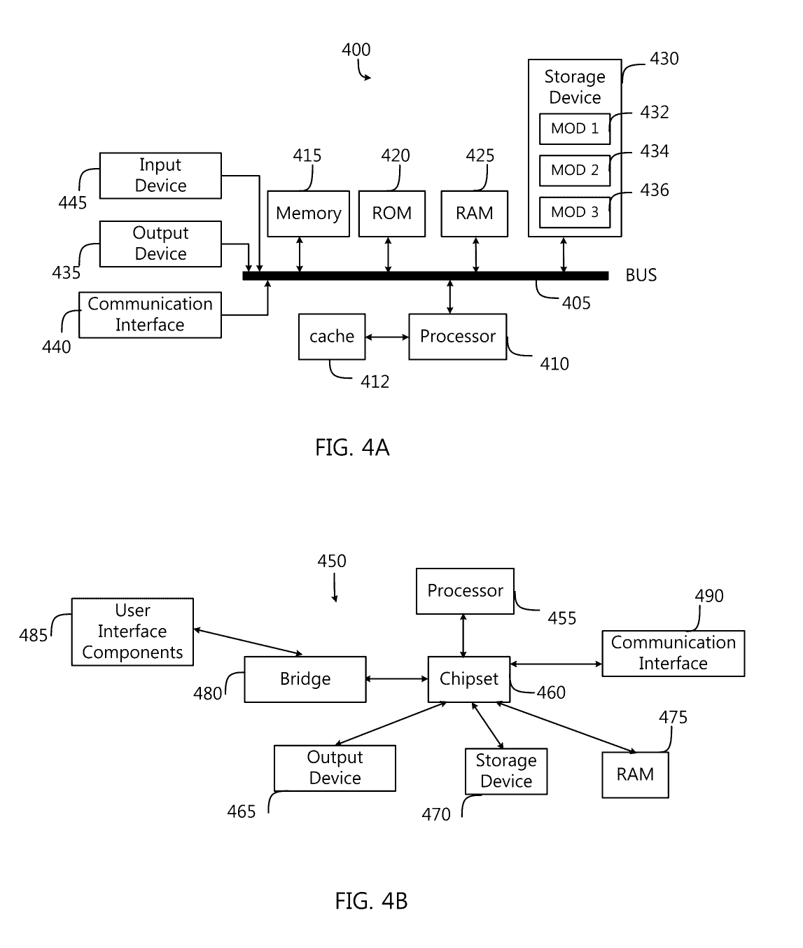

In a network switch system, a lookup database can be maintained to keep track of routes between a number of end points attached to the switch system. However, end points can have various configurations and are associated with numerous tenants. These end-points can have various types of identifiers, e.g., IPv4, IPv6, or Layer-2. The lookup database has to be configured in different modes to handle different types of end-point identifiers. Some capacity of the lookup database is carved out to deal with different address types of incoming packets. Further, the lookup database on the network switch system is typically limited by 1K virtual routing and forwarding (VRFs). Therefore, an improved lookup algorithm is desired to handle various types of end-point identifiers. The disclosed technology addresses the need in the art for address lookups in a telecommunications network. Disclosed are systems, methods, and computer-readable storage media for unifying various types of end-point identifiers by mapping end-point identifiers to a uniform space and allowing different forms of lookups to be uniformly handled. A brief introductory description of example systems and networks, as illustrated in FIGS. 3 and 4, is disclosed herein. These variations shall be described herein as the various examples are set forth. The technology now turns to FIG. 3.

FIG. 3 illustrates an example computing device 300 suitable for implementing at least some aspects of the present technology. Computing device 300 includes a master central processing unit (CPU) 362, interfaces 368, and a bus 315 (e.g., a PCI bus). When acting under the control of appropriate software or firmware, the CPU 362 is responsible for executing packet management, error detection, and/or routing functions, such as miscabling detection functions, for example. The CPU 362 preferably accomplishes all these functions under the control of software including an operating system and any appropriate applications software. CPU 362 can include one or more processors 363 such as a processor from the Motorola family of microprocessors or the MIPS family of microprocessors. In an alternative embodiment, processor 363 is specially designed hardware for controlling the operations of the computing device 300. In a specific embodiment, a memory 361 (such as non-volatile RAM and/or ROM) also forms part of CPU 362. However, there are many different ways in which memory could be coupled to the system.

The interfaces 368 are typically provided as interface cards (sometimes referred to as “line cards”). Generally, they control the sending and receiving of data packets over the network and sometimes support other peripherals used with the computing device 300. Among the interfaces that can be provided are Ethernet interfaces, frame relay interfaces, cable interfaces, DSL interfaces, token ring interfaces, and the like. In addition, various very high-speed interfaces can be provided such as fast token ring interfaces, wireless interfaces, Ethernet interfaces, Gigabit Ethernet interfaces, ATM interfaces, HSSI interfaces, POS interfaces, FDDI interfaces and the like. Generally, these interfaces can include ports appropriate for communication with the appropriate media. In some cases, they can also include an independent processor and, in some instances, volatile RAM. The independent processors can control such communications intensive tasks as packet switching, media control and management. By providing separate processors for the communications intensive tasks, these interfaces allow the master microprocessor 362 to efficiently perform routing computations, network diagnostics, security functions, etc.

Although the system shown in FIG. 3 is one specific computing device of the present technology, it is by no means the only network device architecture on which the present invention can be implemented. For example, an architecture having a single processor that handles communications as well as routing computations, etc. is often used. Further, other types of interfaces and media could also be used with the router.

Regardless of the network device's configuration, it can employ one or more memories or memory modules (including memory 361) configured to store program instructions for the general-purpose network operations and mechanisms for roaming, route optimization and routing functions described herein. The program instructions can control the operation of an operating system and/or one or more applications, for example. The memory or memories can also be configured to store tables such as mobility binding, registration, and association tables, etc.

FIG. 4A, and FIG. 4B illustrate example possible systems in accordance with various aspects of the present technology. The more appropriate embodiment will be apparent to those of ordinary skill in the art when practicing the present technology. Persons of ordinary skill in the art will also readily appreciate that other system examples are possible.

FIG. 4A illustrates a conventional system bus computing system architecture 400 wherein the components of the system are in electrical communication with each other using a bus 405. Example system 400 includes a processing unit (CPU or processor) 410 and a system bus 405 that couples various system components including the system memory 415, such as read only memory (ROM) 420 and random access memory (RAM) 425, to the processor 410. The system 400 can include a cache of high-speed memory connected directly with, in close proximity to, or integrated as part of the processor 410. The system 400 can copy data from the memory 415 and/or the storage device 430 to the cache 412 for quick access by the processor 410. In this way, the cache can provide a performance boost that avoids processor 410 delays while waiting for data. These and other modules can control or be configured to control the processor 410 to perform various actions. Other system memory 415 can be available for use as well. The memory 415 can include multiple different types of memory with different performance characteristics. The processor 410 can include any general purpose processor and a hardware module or software module, such as module 432, module 434, and module 436 stored in storage device 430, configured to control the processor 410 as well as a special-purpose processor where software instructions are incorporated into the actual processor design. The processor 410 can essentially be a completely self-contained computing system, containing multiple cores or processors, a bus, memory controller, cache, etc. A multi-core processor can be symmetric or asymmetric.

To enable user interaction with the computing device 400, an input device 445 can represent any number of input mechanisms, such as a microphone for speech, a touch-sensitive screen for gesture or graphical input, keyboard, mouse, motion input, speech and so forth. An output device 435 can also be one or more of a number of output mechanisms known to those of skill in the art. In some instances, multimodal systems can enable a user to provide multiple types of input to communicate with the computing device 400. The communications interface 440 can generally govern and manage the user input and system output. There is no restriction on operating on any particular hardware arrangement and therefore the basic features here can easily be substituted for improved hardware or firmware arrangements as they are developed.

Storage device 430 is a non-volatile memory and can be a hard disk or other types of computer readable media which can store data that are accessible by a computer, such as magnetic cassettes, flash memory cards, solid state memory devices, digital versatile disks, cartridges, random access memories (RAMs) 425, read only memory (ROM) 420, and hybrids thereof.

The storage device 430 can include software modules 432, 434, 436 for controlling the processor 410. Other hardware or software modules are contemplated. The storage device 430 can be connected to the system bus 405. In one aspect, a hardware module that performs a particular function can include the software component stored in a computer-readable medium in connection with the necessary hardware components, such as the processor 410, bus 405, output device 435 (e.g., a display), and so forth, to carry out the function.

FIG. 4B illustrates a computer system 450 having a chipset architecture that can be used in executing the described method and generating and displaying a graphical user interface (GUI). Computer system 450 is an example of computer hardware, software, and firmware that can be used to implement the disclosed technology. System 450 can include a processor 455, representative of any number of physically and/or logically distinct resources capable of executing software, firmware, and hardware configured to perform identified computations. Processor 455 can communicate with a chipset 460 that can control input to and output from processor 455. In this example, chipset 460 outputs information to output 465, such as a display, and can read and write information to storage device 470, which can include magnetic media, and solid state media, for example. Chipset 460 can also read data from and write data to RAM 475. A bridge 480 for interfacing with a variety of user interface components 485 can be provided for interfacing with chipset 460. Such user interface components 485 can include a keyboard, a microphone, touch detection and processing circuitry, a pointing device, such as a mouse, and so on. In general, inputs to system 450 can come from any of a variety of sources, machine generated and/or human generated.

Chipset 460 can also interface with one or more communication interfaces 490 that can have different physical interfaces. Such communication interfaces can include interfaces for wired and wireless local area networks, for broadband wireless networks, as well as personal area networks. Some applications of the methods for generating, displaying, and using the GUI disclosed herein can include receiving ordered datasets over the physical interface or be generated by the machine itself by processor 455 analyzing data stored in storage 470 or RAM 475. Further, the machine can receive inputs from a user via user interface components 485 and execute appropriate functions, such as browsing functions by interpreting these inputs using processor 455.

It can be appreciated that example systems 400 and 450 can have more than one processor 410 or be part of a group or cluster of computing devices networked together to provide greater processing capability.

For clarity of explanation, in some instances the present technology can be presented as including individual functional blocks including functional blocks comprising devices, device components, steps or routines in a method embodied in software, or combinations of hardware and software.

In some examples, the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Methods according to the above-described examples can be implemented using computer-executable instructions that are stored or otherwise available from computer readable media. Such instructions can comprise, for example, instructions and data which cause or otherwise configure a general purpose computer, special purpose computer, or special purpose processing device to perform a certain function or group of functions. Portions of computer resources used can be accessible over a network. The computer executable instructions can be, for example, binaries, intermediate format instructions such as assembly language, firmware, or source code. Examples of computer-readable media that can be used to store instructions, information used, and/or information created during methods according to described examples include magnetic or optical disks, flash memory, USB devices provided with non-volatile memory, networked storage devices, and so on.

Devices implementing methods according to these disclosures can comprise hardware, firmware and/or software, and can take any of a variety of form factors. Typical examples of such form factors include laptops, smart phones, small form factor personal computers, personal digital assistants, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are means for providing the functions described in these disclosures.

Various aspects of the present technology provide systems and methods for testing a PSU in a server system. While specific examples have been cited above showing how the optional operation can be employed in different instructions, other examples can incorporate the optional operation into different instructions. For clarity of explanation, in some instances the present technology can be presented as including individual functional blocks including functional blocks comprising devices, device components, steps or routines in a method embodied in software, or combinations of hardware and software.

The various examples can be further implemented in a wide variety of operating environments, which in some cases can include one or more server computers, user computers or computing devices which can be used to operate any of a number of applications. User or client devices can include any of a number of general purpose personal computers, such as desktop or laptop computers running a standard operating system, as well as cellular, wireless and handheld devices running mobile software and capable of supporting a number of networking and messaging protocols. Such a system can also include a number of workstations running any of a variety of commercially-available operating systems and other known applications for purposes such as development and database management. These devices can also include other electronic devices, such as dummy terminals, thin-clients, gaming systems and other devices capable of communicating via a network.

To the extent examples, or portions thereof, are implemented in hardware, the present invention can be implemented with any or a combination of the following technologies: a discrete logic circuit(s) having logic gates for implementing logic functions upon data signals, an application specific integrated circuit (ASIC) having appropriate combinational logic gates, programmable hardware such as a programmable gate array(s) (PGA), a field programmable gate array (FPGA), etc.

Most examples utilize at least one network that would be familiar to those skilled in the art for supporting communications using any of a variety of commercially-available protocols, such as TCP/IP, OSI, FTP, UPnP, NFS, CIFS, AppleTalk etc. The network can be, for example, a local area network, a wide-area network, a virtual private network, the Internet, an intranet, an extranet, a public switched telephone network, an infrared network, a wireless network and any combination thereof.

Methods according to the above-described examples can be implemented using computer-executable instructions that are stored or otherwise available from computer readable media. Such instructions can comprise, for example, instructions and data which cause or otherwise configure a general purpose computer, special purpose computer, or special purpose processing device to perform a certain function or group of functions. Portions of computer resources used can be accessible over a network. The computer executable instructions can be, for example, binaries, intermediate format instructions such as assembly language, firmware, or source code. Examples of computer-readable media that can be used to store instructions, information used, and/or information created during methods according to described examples include magnetic or optical disks, flash memory, USB devices provided with non-volatile memory, networked storage devices, and so on.

Devices implementing methods according to this technology can comprise hardware, firmware and/or software, and can take any of a variety of form factors. Typical examples of such form factors include server computers, laptops, smart phones, small form factor personal computers, personal digital assistants, and so on. Functionality described herein also can be embodied in peripherals or add-in cards. Such functionality can also be implemented on a circuit board among different chips or different processes executing in a single device, by way of further example.

In examples utilizing a Web server, the Web server can run any of a variety of server or mid-tier applications, including HTTP servers, FTP servers, CGI servers, data servers, Java servers and business application servers. The server(s) can also be capable of executing programs or scripts in response requests from user devices, such as by executing one or more Web applications that can be implemented as one or more scripts or programs written in any programming language, such as Java®, C, C# or C++ or any scripting language, such as Perl, Python or TCL, as well as combinations thereof. The server(s) can also include database servers, including without limitation those commercially available from open market.

The server farm can include a variety of data stores and other memory and storage media as discussed above. These can reside in a variety of locations, such as on a storage medium local to (and/or resident in) one or more of the computers or remote from any or all of the computers across the network. In a particular set of examples, the information can reside in a storage-area network (SAN) familiar to those skilled in the art. Similarly, any necessary files for performing the functions attributed to the computers, servers or other network devices can be stored locally and/or remotely, as appropriate. Where a system includes computerized devices, each such device can include hardware elements that can be electrically coupled via a bus, the elements including, for example, at least one central processing unit (CPU), at least one input device (e.g., a mouse, keyboard, controller, touch-sensitive display element or keypad) and at least one output device (e.g., a display device, printer or speaker). Such a system can also include one or more storage devices, such as disk drives, optical storage devices and solid-state storage devices such as random access memory (RAM) or read-only memory (ROM), as well as removable media devices, memory cards, flash cards, etc.

Such devices can also include a computer-readable storage media reader, a communications device (e.g., a modem, a network card (wireless or wired), an infrared computing device) and working memory as described above. The computer-readable storage media reader can be connected with, or configured to receive, a computer-readable storage medium representing remote, local, fixed and/or removable storage devices as well as storage media for temporarily and/or more permanently containing, storing, transmitting and retrieving computer-readable information. The system and various devices also typically will include a number of software applications, modules, services or other elements located within at least one working memory device, including an operating system and application programs such as a client application or Web browser. It should be appreciated that alternate examples can have numerous variations from that described above. For example, customized hardware might also be used and/or particular elements might be implemented in hardware, software (including portable software, such as applets) or both. Further, connection to other computing devices such as network input/output devices can be employed.

Storage media and computer readable media for containing code, or portions of code, can include any appropriate media known or used in the art, including storage media and computing media, such as but not limited to volatile and non-volatile, removable and non-removable media implemented in any method or technology for storage and/or transmission of information such as computer readable instructions, data structures, program modules or other data, including RAM, ROM, EPROM, EEPROM, flash memory or other memory technology, CD-ROM, digital versatile disk (DVD) or other optical storage, magnetic cassettes, magnetic tape, magnetic disk storage or other magnetic storage devices or any other medium which can be used to store the desired information and which can be accessed by a system device. Based on the technology and teachings provided herein, a person of ordinary skill in the art will appreciate other ways and/or methods to implement the various aspects of the present technology.

The specification and drawings are, accordingly, to be regarded in an illustrative rather than a restrictive sense. It will, however, be evident that various modifications and changes can be made thereunto without departing from the broader spirit and scope of the invention as set forth in the claims.

What is claimed is:

1. A power supply unit (PSU) comprising:
a plurality of conversion circuits for converting an alternating current (AC) input voltage into a direct current (DC) output voltage;
a first sensing circuit coupled to one of the plurality of conversion circuits, the first sensing circuit configured to sense a value of a performance characteristic of a first component of the plurality of conversion circuits; and
a first multipoint control unit (MCU) coupled to at least one of the plurality of conversion circuits,
wherein the first MCU is configured to control the plurality of conversion circuits based at least upon the DC output voltage and to generate a first alarm signal in response to the value of the performance characteristic of the first component being inconsistent with a first criterion.

2. The power supply unit of claim 1, wherein the first criterion includes a range of voltage, current, or impedance value of the first component.

3. The power supply unit of claim 1, wherein the first sensing circuit is one of a voltage comparator, a current sensing circuit, or an impedance sensing circuit.

4. The power supply unit of claim 1, wherein the plurality of conversion circuits includes components of the PFC circuit, the DC-DC converter, the transformer, the first rectifier, an EMI filter, a second rectifier, an ORing device, and a photocoupler.

5. The power supply unit of claim 1, wherein the first criterion is predetermined or dynamically determined using one or more machine learning algorithms based upon historical data of the performance characteristic of the first component of the PSU.

6. The power supply unit of claim 5, wherein the historical data of the performance characteristic of the first component includes a service time of the PSU and loading information of the PSU during the service time.

7. The power supply unit of claim 1, wherein the first MCU is coupled to the first output of the first rectifier via a photocoupler and a second MCU; wherein the second MCU is also coupled to a second output of the rectifier and a second sub-circuit, the second sub-circuit configured to sense a value of a performance characteristic of a second component at a secondary side of the transformer.

8. The power supply unit of claim 7, wherein the second MCU is configured to generate a second alarm signal in response to the value of the performance characteristic of the second component being inconsistent with a second criterion.

9. The power supply unit of claim 7, wherein, in response to the value of the performance characteristic of the second component being inconsistent with a second criterion, the second MCU is configured to send an output signal to the first MCU via the photocoupler.

10. The power supply unit of claim 7, wherein, in response to the value of the performance characteristic of the second component being inconsistent with a second criterion, the second MCU is configured to send an output signal to a controller outside the PSU via a serial peripheral interface (SPI) bus, an inter-integrated circuit (I2C) bus, a power management bus (PMBus), a controller area network (CAN) bus, or a bus that supports an electronic industries alliance (EIA), RS-232, RS-422, or RS-485 standard.

11. A computer-implemented method for testing a power supply unit (PSU) in a rack system, comprising:
determining that the PSU is electrically connected to the rack system;
determining a first value of an output voltage of the PSU;
managing the PSU based at least upon the first value of the output voltage of the PSU;
determining, by a first sub-circuit of the PSU, a value of a performance characteristic of a first component of the PSU; and
in response to the value of the performance characteristic of the first component being inconsistent with a first criterion, generating a first alarm signal.

12. The computer-implemented method of claim 11, wherein the first criterion includes a range of voltage, current or impedance value of the first component.

13. The computer-implemented method of claim 11, wherein the first sub-circuit is one of a voltage comparator, a current sensing circuit, or an impedance sensing circuit.

14. The computer-implemented method of claim 11, wherein the first component is one of components of the PSU that includes a PFC circuit, a DC-DC converter, a transformer, a first rectifier, an EMI filter, a second rectifier, an ORing device, and a photocoupler.

15. The computer-implemented method of claim 11, further comprising:
determining, based upon historical data of the performance characteristic of the first component of the PSU, the first criterion using one or more machine learning algorithms.

16. The computer-implemented method of claim 15, wherein the historical data of the performance characteristic of the first component includes a service time of the PSU and loading information of the PSU during the service time.

17. The computer-implemented method of claim 11, further comprising:
determining, by a second sub-circuit of the PSU, a value of a performance characteristic of a second component at a secondary side of a transformer of the PSU.

18. The computer-implemented method of claim 17, further comprising:
in response to the value of a performance characteristic of the second component being inconsistent with a second criterion, generating a second alarm signal.

19. The computer-implemented method of claim 17, further comprising:
in response to the value of a performance characteristic of the second component being inconsistent with a second criterion, sending an output signal to a controller outside the PSU via a serial peripheral interface (SPI) bus, an inter-integrated circuit (I2C) bus, a power management bus (PMBus), a controller area network (CAN) bus, or a bus that supports an electronic industries alliance (EIA), RS-232, RS-422, or RS-485 standard.

20. A non-transitory computer-readable storage medium including instructions that, when executed by at least one processor of a computing system, cause the computing system to:
determine that a power supply unit (PSU) is electrically connected to the rack system;
determine a first value of an output voltage of the PSU;
manage the PSU based at least upon the first value;
determine, by a first sub-circuit of the PSU, a value of a performance characteristic of a first component of the PSU; and
in response to the value of the performance characteristic of the first component being inconsistent with a first criterion, generate a first alarm signal.
